(19) United States
(12) Patent Application Publication
(10) Pub. No.: US 2024/0169242 A1
(43) Pub. Date: May 23, 2024

(54) QUBIT AND QUANTUM PROCESSING SYSTEM

(71) Applicant: Silicon Quantum Computing Pty Limited, Kensington, New South Wales (AU)

(72) Inventors: Samuel Keith Gorman, New South Wales (AU); Michelle Yvonne Simmons, New South Wales (AU); Felix Krauth, New South Wales (AU); Yu He, New South Wales (AU)

(73) Assignee: Silicon Quantum Computing Pty Limited, Kensington, New South Wales (AU)

(21) Appl. No.: 18/550,118

(22) PCT Filed: Mar. 11, 2022
(86) PCT No.: PCT/AU2022/050205

§ 371 Date: Sep. 11, 2023

(30) Foreign Application Priority Data
Mar. 11, 2021 (AU) 2021900702

(51) Int. Cl. G06N 10/40; G06N 10/20

(52) U.S. Cl. CPC G06N 10/40; G06N 10/20

(57) ABSTRACT

A quantum bit, quantum processing element, and one or more large-scale quantum processing systems are disclosed. the quantum bit includes: a first quantum dot embedded in the semiconductor substrate, the first quantum dot comprising a first donor atom cluster and a second quantum dot embedded in the semiconductor substrate, the second quantum dot comprising a second donor atom cluster. The first and second quantum dots share a single electron, and the quantum bit is electrically controlled utillising the hyperfine interaction between the single electron and one or more nuclear spins present in the first and second donor atom clusters.

### TECHNICAL FIELD

Aspects of the present disclosure are related to quantum processing systems and more particularly to silicon-based quantum processing systems and qubits.

### BACKGROUND

Universal quantum computing holds promise to vastly improve computing power and open entirely new fields to analytical study. However, at present, the design and operation of quantum computers is limited by imprecision in fabrication and noise inherent in such devices.

Designs and operation strategies, which are resilient to noise and imprecision, will significantly aid the realization of a universal quantum computer.

### SUMMARY

According to a first aspect of the present disclosure there is provided a quantum bit comprising: a first quantum dot embedded in the semiconductor substrate, the first quantum dot comprising a first donor atom cluster; a second quantum dot embedded in the semiconductor substrate, the second quantum dot comprising a second donor atom cluster; wherein the first and second quantum dots share an electron; and wherein the quantum bit is electrically controlled based on hyperfine interaction between the electron and one or more nuclear spins present in the first and second donor atom clusters.

In some example embodiments the first donor atom cluster includes an even number of atoms and the second donor atom cluster includes an odd number of atoms. The nuclear spin of all the atoms in the first donor atom cluster, and nuclear spin of all but one atom in the second donor atom cluster are initialized in opposite directions, so as to cancel out their spin magnetic moment. The nuclear spin of all but one atom in the second donor atom cluster is initialized in the spin up direction.

Further in some other examples, the first and/or second donor atom clusters are loaded with electron pairs to decrease the strength of the hyperfine interaction and reduce a longitudinal energy gradient of the quantum bit.

According to another aspect of the present disclosure there is provided a quantum processing element, comprising: a semiconductor substrate and a dielectric material forming an interface with the semiconductor substrate; a quantum bit comprising: a first quantum dot embedded in the semiconductor substrate and comprising a first donor atom cluster, a second quantum dot embedded in the semiconductor and comprising a second donor atom cluster, the first and second quantum dots sharing an electron; and one or more gates for controlling the quantum bit. The quantum bit is tuned such that the electron spin hybridizes with the electron's orbital wave function, allowing electric control of the quantum bit.

According to yet another embodiment of the present disclosure, there is provided a large scale quantum processing architecture comprising: a plurality of nodes, each node comprising a semiconductor substrate and a dielectric material forming an interface with the semiconductor substrate, each node further comprising a plurality of qubits embedded within the substrate, wherein each qubit includes two quantum dots, each quantum dot including a donor atom cluster and an electron shared between the two quantum dots, the node further comprising a plurality of gates for controlling the plurality of qubits; and superconducting cavities arranged between neighboring nodes of the plurality of the nodes, each superconducting cavity coupling an edge qubit of a node with a corresponding edge qubit of a neighboring node.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF THE DRAWINGS

FIG. 1A shows an example flopping mode qubit.

FIG. 1B shows another example flopping mode qubit.

FIG. 2 is a schematic diagram of an exemplary flopping mode qubit according to aspects of the present disclosure.

FIG. 3A shows an energy level diagram of a 2P-1P system.

FIG. 3B shows a table of different nuclear spin and electron configurations and the effect of these configurations on the value of the longitudinal energy gradient ΔΩ_{∥}.

FIG. 3C shows the four main branches of the energy spectrum of a single electron orbiting two quantum dots coupled by a tunnel coupling t_{c}, as a function of the electric detuning between the two quantum dots, in a fixed magnetic field.

FIG. 3D shows simulated leakage probability for two leakage pathways during initialisation ramp as a function of ramp time for a 2P-1P (3 electron) system.

FIG. 4A shows the energy level diagram of a 2P-1P system, as a function of electric detuning ε.

FIGS. 4B shows the dipole coupling strength between the qubit ground and the remaining states of a 2P-1P system;

FIGS. 4C shows the dipole coupling strength between the qubit excited state and the remaining states of a 2P-1P system;

FIG. 5A shows two leakage populations during π/2−X Gaussian pulse for the donor-donor qubit

FIG. 5B shows π/2−X gate errors of the qubit of FIG. 2.

FIG. 5C shows strong coupling of the all-epitaxial flopping mode qubit to a superconducting cavity resonator.

FIG. 6 shows a top view of a large-scale quantum computing system according to embodiments of the present disclosure.

FIG. 7 is a perspective view of a dipole-coupled node according to some embodiments of the present disclosure;

FIG. 8 is a flowchart illustrating an example method for fabricating a dipole-coupled node according to some embodiments of the present disclosure;

FIG. 9 shows a top view of a floating gate coupled node according to some embodiments of the present disclosure; and

FIG. 10 shows a perspective view of a floating gate coupled node according to some embodiments of the present disclosure.

### DETAILED DESCRIPTION

One type of quantum computing system is based on spin states of individual qubits where the qubits are electron and/or nuclear spins localized inside a semiconductor quantum chip. These electron and/or nuclear spins are confined either in gate-defined quantum dots or on donor atoms that are positioned in a semiconductor substrate.

Such spin-based qubits can be driven and/or addressed magnetically or electrically. Although high-frequency magnetic fields allow for high-fidelity single and two-qubit gates in silicon-based qubits, the technical complexity of generating local oscillating magnetic fields on the nanometer length scales remains a significant hurdle for the future scalability of magnetic control. Further, when qubits are driven magnetically, typically, an on-chip magnetic field generator is required which takes up precious real estate on the quantum processor chip. Further still, to magnetically drive spin qubits, more power is required—for instance to power the on-chip magnetic field generator.

To address some of these issues, spin qubits can be electrically driven. In certain examples, electric dipole spin resonance (EDSR) may be utilized to control spin qubits with local electric fields. EDSR is generally achieved by coupling the spin of a qubit to the charge degree-of-freedom. This spin-charge coupling can be induced by a spin-orbit interaction. This so-called spin-orbit coupling (SOC) is generally present in atoms and solids—due to a relativistic effect, electrons moving in an electric-field gradient experience in their reference frame an effective magnetic field. In the case of silicon, however, SOC is intrinsically weak.

To increase the strength of SOC, several different mechanisms can be used such as the use of large spin-orbit coupling materials and gradient magnetic fields from micro-magnets.

By using a hyperfine interaction between electrons and surrounding nuclear spins, qubits can be electrically controlled without needing any additional control elements such as magnetic field generators, etc., and less power is needed to control the operation of the qubits.

Another advantage of using electrically controlled qubits is seen when large-scale quantum processors are fabricated. As quantum processors become larger, more and more qubits and control structures need to be in a small space. This reaches a natural limit, as only a limited number of qubits can be located on a given chip. In such cases, to increase the computational complexity of the quantum processor, multiple qubit chips are coupled to each other. In order to enable this coupling, qubits need to be coupled over long distances (i.e., the distance between the quantum chips).

This long-distance coupling has traditionally been difficult given that exchange interaction between qubits decays exponentially with qubit separation and is highly dependent on the placement of qubits being within a few nanometers of each other.

One realistic way of coupling qubits over longer distances (e.g., over hundreds of nanometers and up to hundreds of micrometers) is to use electrical coupling and superconducting cavities between adjacent qubit chips. In such cases, the electrical mechanism used to control or drive qubits can also be used to electrically couple qubits over long distances.

The present disclosure provides a new type of qubit (and a new type of flopping mode qubit) that can be electrically controlled and a new method for controlling the newly disclosed qubit with electric fields. The qubits manipulated in accordance with the disclosed methods can be separated by hundreds of nanometers and up to hundreds of micrometers while preserving coupling capabilities. This substantially relaxes the precision requirements for inter-qubit distance during quantum chip fabrication processes as there is no need to fabricate qubits and other components at a small scale of few atoms. Furthermore, the present disclosure allows feasibility of large-scale quantum computing processors for which coupling between distant qubits on the same or separate quantum chips will be possible.

### Flopping Mode Qubits

In the past few years, several different types of flopping mode qubits have been introduced, which can be driven electrically. Flopping-mode qubits are based on a single electron spin that can be in two different charge states. By carefully tuning of the electric field E, the electron can be put into a charge superposition between the two sites (forming a charge qubit). If the electron spin Zeeman splitting is comparable to the charge qubit splitting, then the spin and charge states of the electron become hybridized. The hybridization results in a spin-charge coupling proportional to the difference in transverse terms on each site.

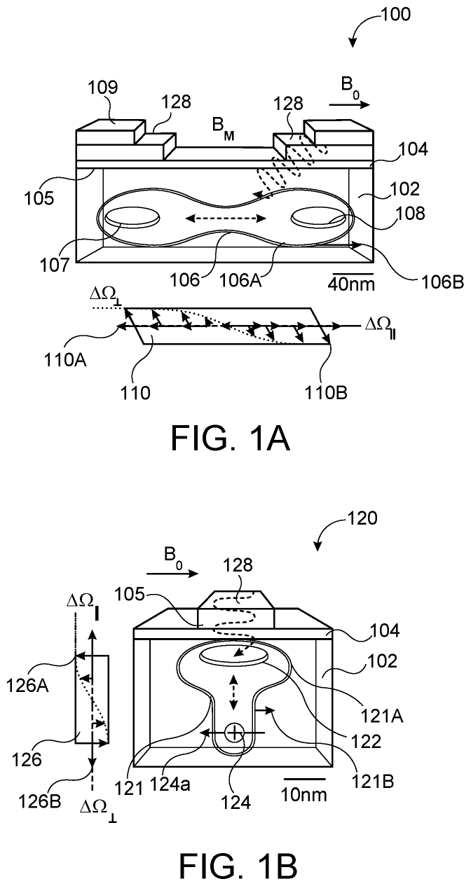

FIG. 1A and FIG. 1B illustrate two types of flopping mode qubits which are electrically driven.

In particular, FIG. 1A shows a processing element or qubit device 100 that includes a semiconductor substrate 102 and a dielectric 104. In this example, the semiconductor substrate is isotopically purified silicon-28 and the dielectric is silicon dioxide. The semiconductor substrate 102 and dielectric 104 form an interface 105, which in this example is a Si/SiO₂ interface. The processing element 100 includes a qubit 106. The qubit 106 is formed of two quantum dots 107 and 108 sharing a single electron, (wave function 106A, and electron spin 106B). The qubit 106 can be created in the semiconductor substrate 102 using any one of the various available methods to produce quantum dots in silicon. Electric confinement of the electron with respect to the two quantum dots (107, 108) is achieved by gates 128 positioned on the dielectric 104. In addition, a micromagnet 109 is positioned on the gate 128 (approximately 300 nanometers away from the qubit 106). The micromagnet 109 generates a large local magnetic field gradient (>400 MHz) across the quantum dots (107, 108) with longitudinal and transverse components that differs at the two quantum dot sites. The resulting longitudinal and transverse energy gradients ΔΩ_{∥} and ΔΩ_{⊥} are displayed in 110. In particular, the longitudinal energy gradients are labeled as 110A (in the direction of ΔΩ_{∥}), and the transverse energy gradients are labelled as 110B (in the direction of ΔΩ_{⊥}.

Further, the micromagnet 109 enables EDSR and gives rise to spin-orbit coupling (SOC). The gate 128 can be used to induce an AC electric field which moves the electron within the fixed magnetic field gradient of the micromagnet and thus modulates the magnetic field the electron experiences in its frame of reference. It can also be used for readout of the qubit state. In other words, a flopping-mode EDSR is performed by biasing the unpaired electron into a superposition between two charge states of the two quantum dots (106, 108) and applying an oscillating electric field at a frequency on resonance with the qubit energy. The qubit 106 of FIG. 1A is often called a double quantum dot qubit.

FIG. 1B illustrates another example of a known flopping mode qubit—called a flip-flop qubit. In this arrangement, one of the quantum dots (as shown in the flopping mode qubit 106) is replaced by a donor. In the flip-flop qubit the spin charge coupling arises from the hyperfine interaction of the electron spin with a nuclear spin of a single phosphorus donor which can be used to generate electron-nuclear spin flip-flop transitions. The flopping-mode operation EDSR is performed by positioning the electron in a superposition of charge states between the donor nuclei and an interface quantum dot created using electrostatic gates. In this charge superposition state, the hyperfine interaction changes significantly for small changes in detuning.

In particular, FIG. 1B shows a quantum processing device 120 including a flopping mode qubit 121. The qubit 121 is formed of one quantum dots 122 and one donor atom 124 sharing a single electron, wave function 121A, and electron spin 121B. The quantum processing device 120 includes a semiconductor substrate 102 and a dielectric 104. In this example, the semiconductor substrate is silicon-28 and the dielectric is silicon dioxide (SiO₂). The semiconductor substrate and dielectric form an interface 105, which in this example is a Si/SiO₂ interface. The donor atom 124 is located within the substrate 102 and the quantum dot 122 is formed near the interface 105 to confine the electron of the donor atom 124. A gate 128 is positioned above the quantum dot 122 (on the dielectric 104). The donor atom 124 can be introduced into the substrate 102 using nanofabrication techniques, such as hydrogen lithography provided by scanning-tunneling-microscopes or using ion implantation techniques.

The gate electrode 128 is operable to interact with the donor atom 124. For example, the gate 128 may be used to induce an AC electric field in the region between the interface 105 and the donor atom 124 to modulate a hyperfine interaction between the electron located at the quantum dot 122 and the donor nuclear spin 124a.

When electrically driving the qubit, the electron spin 121B flip-flops with the nuclear spin 124a of the donor. That is, the electric field can be used to control the quantum state of the qubit associated with the pair of electron-nuclear spin eigenstates i.e., ‘electron spin-up, nuclear spin-down’ and ‘electron spin-down, nuclear spin-up’. The resulting longitudinal and transverse energy gradients ΔΩ_{∥} and ΔΩ_{⊥} are displayed in 126. In particular, the longitudinal energy gradients are labeled as 126A and the transverse energy gradients are labelled as 126B.

These types of flopping-mode qubits (106 and 121) have some disadvantages. For instance, some implementations of flopping mode qubits, such as qubit 106, includes two quantum dots formed at the interface 105 between the substrate 102 and the dielectric 104. This interface 105 generally has several imperfections and sources of noise, such as dangling bonds, generally making the qubit more sensitive to the environmental noise—which is detrimental for qubits. Further, device 100 utilizes micromagnets 109 to generate the magnetic field gradient required to engineer the SOC and as discussed previously micromagnets take up valuable chip real estate. Additionally, this quantum processing device 100 requires precise design and fabrication of the micromagnet 109 in order to engineer the desired highly localized spatial field gradient—which is often very difficult to achieve.

Although the device 120 of FIG. 1B does not need a micromagnet and includes a donor atom within the substrate (and away from the interface 105) it still includes a quantum dot formed at the interface 105 by a gate 128, which leads to the same detrimental effects on the qubit as discussed with reference to device 100.

### Novel Flopping Mode Qubit Structure

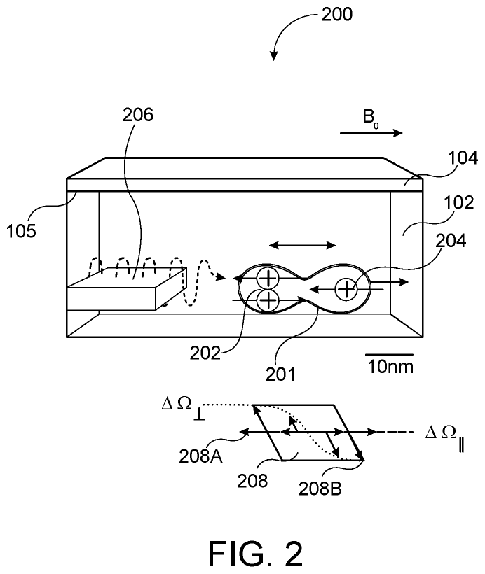

FIG. 2 illustrates an example quantum processing device 200 comprising a flopping mode qubit 201 introduced by the present disclosure. The flopping mode qubit 201 in FIG. 2 includes two quantum dots 202 and 204. Each quantum dot consists of a donor cluster. The qubit 201 uses a hyperfine interaction from the electron-nuclear system naturally present in donor systems to generate a synthetic spin-orbit coupling (SOC).

The whole device 200 is epitaxial—i.e., the donor clusters 202, 204 are fabricated within the substrate 102 and far from the interface 105. As described previously, the Si/SiO₂ interface 105 is generally rough and may have various noise sources. Positioning the donor clusters of qubit 201 away from the interface 105 significantly reduces impact of noise on the qubit 201. In some examples, the qubit 201 and its donor clusters are formed about 20-50 nm from the interface 105 and separated by approximately 10-15 nm.

Each qubit may be controlled by one or more gates (one gate 206 shown here). In one implementation, the gates 206 may be metal contacts on the surface. In another implementation, the gates may be phosphorus-doped silicon (Si:P) gates fabricated epitaxially within the semiconductor substrate 102. In either case, the control gates 206 allow full electrostatic control of the qubit 201. DC electric fields, fast electric pulses and microwave (MW) electric fields can be applied on those two gates, either separately or jointly. The different controls can be added on chip using bias tees (not shown).

In some embodiments, one of the gates 206 is tunnel coupled to one of the quantum dots (202, 204) in the pair, to allow loading and unloading electrons onto the qubit 201. Due to the increased electrostatic coupling of that gate 206 to the qubit 201, it is advantageous to use that gate to drive the qubit.

In the most basic implementation, a global or local nuclear magnetic resonance (NMR) antenna allows control of the nuclear spins of the donors via radio frequency (RF) magnetic fields in the range of about one hundred MHz. The NMR antenna (not shown) can be manufactured on chip, or off chip (cavity or coil). The control of the nuclear spins is necessary for optimal operation of the qubit since the dephasing rate and spin-charge coupling depend on the orientation of the nuclear spins with respect to the electron spin state. Further, the longitudinal and transverse energy gradients ΔΩ_{∥} and ΔΩ_{⊥} are displayed in 208. In particular, the longitudinal energy gradients are labeled as 208A and the transverse energy gradients are labelled as 208B.

Qubit readout can be performed with a separate charge sensor (not shown) or dispersively using one of the two gates 206 mentioned previously. The charge sensor can be implemented with various structures. Examples of charge sensors that could be used are: a single electron transistor (SET), a single electron box (SEB), and a tunnel junction. The use of dedicated charge sensor allows for direct spin readout of the electron and nuclear spins states. However, dispersive readout using a nearby gate reduces the device complexity and instead measures the charge state of the qubit.

The qubit device 200 as well as some electronics structures used for readout and control of the qubit 201 needs to be cooled to sub-Kelvin temperatures using a dedicated dilution refrigerator. The sample is permeated by a static magnetic field B of the order of a few hundreds of milli-Tesla.

Electronic structures necessary for readout and control can be placed on chip, or on the printed circuit board (PCB) which holds the silicon chip. They include: waveguides, resonators, bias tees, amplifiers, filters, mixers circulators, etc. Any of these structures can be implemented using on chip lithographic structures or on the PCB using commercially available surface mount devices (SMD).

In the flopping mode qubits shown in FIGS. 1A, 1B and 2, different mechanisms—i.e., the micromagnet in qubit device 100 or electron-nuclear hyperfine interaction in qubit devices 120 and 200, facilitates an effective energy gradient oriented along a transverse direction with respect to the external magnetic field—the magnetic field along this direction is used to drive the qubit. In addition, the mechanism also produces an energy gradient ΔΩ_{⊥} (110B, 126B, 208B) in the direction perpendicular to the static magnetic field B0 which defines the longitudinal direction. Typically, the energy gradient ΔΩ_{∥} (110A, 126A 208A) in the longitudinal direction is detrimental to the operation of qubits. In previous publications, it was shown that this longitudinal gradient ΔΩ_{∥} (110A, 126A 208A) could produce a second order sweet spot (i.e., a location in the qubit operation parameter space where the qubit is protected against charge noise to second order) which leads to lower charge noise in the qubit. Accordingly, previously known systems did not attempt to minimize this longitudinal gradient.

The inventors of the present application however have identified that qubits perform better when the longitudinal energy gradient is minimized. When the longitudinal energy gradient is minimized, it was found that the qubits exhibit fewer errors because the qubits are better protected against charge noise than when the longitudinal energy gradient is not minimized. Further, it was found that when the longitudinal gradient is minimized, the qubits could be driven with smaller powers, which is important as it reduces the power requirements and reduces the overall heat generated by the chip. In addition, when the longitudinal energy gradient is reduced the qubit can be coupled to a superconducting cavity using more realistic coupling strength between the qubit and the superconducting cavity.

In the case of qubit device 100, which uses a micromagnet 109 to generate the localized magnetic field, the longitudinal gradient is always generated by the micromagnet 109 and can only be minimized by reengineering the micromagnet 109—which is difficult. In the case of qubit device 120, the longitudinal gradient is produced by a difference in spin orbit coupling between the quantum dot 122 near the interface and the donor atom 124. The donor atom in qubit 120 is placed via ion implantation, which is not deterministic and cannot guarantee that the donor atom is placed at the one optimal orientation with respect to electric and magnetic fields that minimizes the longitudinal gradient.

The inventors of the present disclosure found that it was possible to minimize the longitudinal gradient of qubit 201 by manipulating/controlling the nuclear spins of those donors within the donor clusters which do not flip during the qubit electric driving. We refer to those nuclear spin as “spectator nuclear spins”. In particular, the longitudinal gradient is given by the sum of the hyperfine coupling to the spectator nuclear spins ΣAᵢ [symbol] i_{z} [symbol] , where Aᵢ is the hyperfine strength of the i spectator nuclear spin and [symbol] i_{z} [symbol] is the expectation value of the z-projection of the nuclear spin state. For an even number of nuclear spins in a cluster, the longitudinal gradient can vanish if the nuclear spins are initialized in opposite directions, ΣAᵢ [symbol] i_{z} [symbol] =0. The example displayed in FIG. 2 consists of a 2P cluster on the left quantum dot and a 1P cluster on the right quantum dot. It is advantageous to define the qubit using the nuclear spin state of the 1P cluster, so that all spectator nuclear spins are contained in the leftmost 2P cluster. The hyperfine couplings of an electron to each donor within the same cluster are usually similar, Aᵢ≈A. By initializing the two nuclear spins in opposite directions, the longitudinal gradient vanishes, ΣAᵢ [symbol] i_{z} [symbol] =A(+1)+A(−1)=0. In one example, the longitudinal gradient can be minimized by initializing the donor nuclear spins in one of the quantum dots in opposite directions—thereby cancelling the longitudinal gradient. In another example, the longitudinal gradient can be minimized by adding more electrons to donor cluster of one of the quantum dots. Further still, in some embodiments, both these techniques can be used together.

The qubit device 200 is tuned in such a way that an unpaired electron spin, trapped in the qubit 201 hybridizes with the electron's orbital wave function, allowing strong electric drive of the electron's spin qubit via its orbital state. Further, as discussed above, NMR control of the nuclear spins within the donor clusters allows engineering of the longitudinal energy gradient in such a way as to significantly increase the resilience of the qubit to charge noise, and to imprecisions in donor placements.

The electron orbital on the left quantum dot 202 is denoted as |L [symbol] and the electron orbital on the right quantum dot 204 is denoted as |R [symbol] . The transition probability between the two electron orbitals is described by the tunnel coupling t_{c}. The tunnel-coupling itself depends on the distance between the quantum dots 202 and 204, the number of donors within each cluster and the number of inner shell electrons on each cluster that smoothen out the potential of the donor for the outer shell one that defines the qubit.

A static electric field E across the double quantum dot 201 allows to control the potential energy difference ϵ=eE_{d}/h between the two quantum dot orbitals (in angular frequency units). Using the static field, the electron's spin state (|↑ [symbol] , |↓ [symbol] ) can be controllably hybridized with the electron's orbital state. The static electric field also allows controlling the contact hyperfine interaction (of the electron's spin with the nuclei in the two quantum dots 202, 204.

In certain embodiments, the donor atoms are phosphorus atoms and the number of phosphorus atoms in the two quantum dots can vary. In one preferred implementation, the double dot system is an nP-1P system such that one quantum dot includes n number of phosphorus atoms whereas the other quantum dot includes one phosphorus atom. In more preferred embodiments, the double dot system may be a 2P-1P system such that it includes two phosphorus donors (2P) on one quantum dot 202, and a single phosphorus donor (1P) on the other quantum dot 204. In this implementation, the 2P donor atoms can be used as spectator nuclear spins, whereas the 1P donor atom is used for driving the qubit. Three electrons can be loaded on the qubit 201, in such a way that two electrons pair up on the 2P (where their influence can be neglected, while the last electron is unpaired and is the one participating in the qubit). Although the examples described herein utilize the 2P-1P arrangement of donor atoms in the quantum dots, it will be appreciated that the presently disclosed qubits and systems are not limited to this arrangement. Instead, the qubit may have any other arrangement such as nP-mP, where the left quantum dot is formed by a cluster of n donors, and the right quantum dot by m donors.

Qubit 201 consists of two levels chosen within a larger subspace of states. The full Hilbert space of the system is spanned by the electron's two orbital states |L [symbol] and |R [symbol] corresponding to the electron fully occupying the dots labelled as “left” or “right” respectively, the electron's spin orientation |↑ [symbol] and |↓ [symbol] , and the nuclear spin orientation [symbol] and [symbol] of each of the N_{d} donors within the quantum dots. The full Hilbert space can be decomposed into a direct sum of invariant subspaces according to their total electron and nuclear spin magnetization number m:

$${f}_{} = \begin{matrix}{N}_{s} / 2 \\ ⊕ \\ m = - {N}_{s} / 2\end{matrix} {m}_{{N}_{s}}^{} ⊗ {c}_{} \qquad ( 1 )$$

Where Nₛ=N_{d}+1 is the total number of spins in the system (nuclear and electron), and H_{c} is the charge Hilbert space spanned by the two orbital states.

Transitions between different subspaces [symbol] ₘ^{N}^{ₛ}⊗ [symbol] _{c} are forbidden due to spin conservation. Only when using NMR pulses to initialize the nuclear spins in the chosen subspace, is it possible to transition between them (discounting nuclear or electron spin relaxation). The dimension of each invariant subspace is simply given by the binomial coefficients:

$$dim ( {ℋ}_{m}^{{N}_{s}} ) = ( \begin{matrix}{N}_{s} \\ m + \frac{{N}_{s}}{2}\end{matrix} ) . \qquad ( 2 )$$

Any of the invariant subspaces above offers a possibility of a flip-flop transition with a nuclear spin, baring the two one-dimensional spaces [symbol] _{±N}_{ₛ}_{/2}. The Nₛ=2 case (i.e., only one donor in the system) is the only case where one of the subspaces already is two-dimensional and offers a natural platform for a qubit. If there is more than one donor atom in the system (Nₛ>2), the invariant subspaces have dimensions larger then 2, resulting from the fact that the electron spin can flip-flop with more than one nuclear spin. The table below highlights the dimension of the spin subspaces of the same magnetization, for different donor numbers N_{d}. Nₛ denotes the number of spins in the systems (donors and electron), while N_{d} denotes the number of donors. The actual dimension of the subspaces is twice the one displayed here, as the charge subspace is two-dimensional. As such the table below shows the dimension of the spin subspaces for one of the charge degrees of freedom.

TABLE 1
Dimensions of the invariant spin subspaces of same magnetization
m for a given charge degree of freedom.

| | | m | | | | | | | | | | |
|---|---|---|---|---|---|---|---|---|---|---|---|---|
| Nₛ | N_{d} | −5/2 | −2 | −3/2 | −1 | −1/2 | 0 | 1/2 | 1 | 3/2 | 2 | 5/2 |
| 2 | 1 | | | | 1 | | 2 | | 1 | | | |
| 3 | 2 | | | 1 | | 3 | | 3 | | 1 | | |
| 4 | 3 | | 1 | | 4 | | 6 | | 4 | | 1 | |
| 5 | 4 | 1 | | 5 | | 10 | | 10 | | 5 | | 1 |

It will be appreciated that it is not an inherent issue to have the qubit states coupled to a larger Hilbert space. Superconducting transmon qubits for example consist of the two lowest harmonic oscillator states, even though coupling to higher energy states is possible. However, provided none of the qubit states are degenerate, one can fully remain within the qubit subspace by performing an appropriate initialization and by driving adiabatically at the frequency defined by the qubit splitting. The individual coupling strengths and energy spacing all determine how fast a transition can be driven adiabatically, without leaking into the other states. The superconducting community has done extensive work to design pulses sequences that reduce leakages to non-qubit subspaces while allowing fast driving, and thus minimize the influence of dephasing and relaxation errors.

In the implementation consisting of a 2P-1P system 201 for example, there are five invariant subspaces with magnetization m=−2, −1, 0, 1, 2 and respective dimensions dim=2, 8, 12, 8, 2 (including charge). The m=±2 subspaces correspond to all the spins being polarized in the same direction: | [symbol] and | [symbol] respectively. Those two subspaces are two-dimensional as the electron has no nuclear spin of opposite orientation to flip-flop with, and only the charge state can be changed. Through NMR control, the nuclear spin can be initialized in any of the three other subspaces. The m=0 subspace is especially attractive as the spectator nuclear spin can be initialized in such a way as to minimize the effective longitudinal magnetic field gradient for overall enhanced qubit performance.

### Qubit Operation

The qubit 201 can be incorporated in various implementations of a universal quantum computer, provided it can be initialized, measured and fully controlled, and an entangling gate between two such qubits is possible. The unavoidable errors in those operations however need to be lower than the error threshold of the error correction algorithm running on the quantum computer for the latter to work.

Disclosed herein is an implementation of a universal quantum computer using a specific error detection and correction code called “surface code”. The surface code has an error threshold of about 1%. All operations proposed herein can be implemented below that threshold.

Some of the qubit operations are possible when the qubit is in a hybridized spin-charge state while other operations can be implemented when the qubit is in its pure spin state. The qubit state can be adiabatically transferred between those two regimes. In the hybridized regime (two-dot regime), the electron wave function is tuned in such a way that the qubit is sensitive to electric field, allowing electric driving, qubit readout and qubit coupling via it's charge component. In this state the qubit is however prone to decoherence due to electric field noise (charge noise), and relaxation due to the increased charge character of the qubit. In the purely spin regime (single dot regime), the electron wave function is tuned by static electric fields such that it is fully centered on one of the donor clusters. In this regime, the qubit cannot be driven, readout via the charge state or coupled electrically. However, it is very resilient to electric noise, and boasts high coherence and relaxation times associated with electrons spins on donor clusters. Qubit readout via electron spin readout is possible in this regime.

It will be appreciated that if an electrometer such as an SET is employed for spin readout, the qubit readout will be sensitive to spin and the qubit 201 can be read out in its idle state. Alternatively, if other means for readout are employed, such as dispersive readout or cavity readout, the qubit readout will be sensitive to the charge character of the qubit and the readout is performed when the electron spin is hybridized to its orbital, i.e., when the spin and charge are hybridized.

To perform any function, a qubit 201 first needs to be initialized. Initializing the qubit 201 in its ground state is possible through a combination of NMR pulses initializing the nuclear spins and spin selective tunneling of an electron spin-down from a nearby reservoir (e.g., gate 206). The spin selective tunneling also automatically initializes the electron's charge state into the ground charge state. Indeed, electron tunneling is most practically performed when the static electric fields is biased far away from the hybridized regime, in such a way that the orbital of the dot closest to the reservoir is in the ground state (e.g., the right dot 204, without loss of generality). In that far detuned region, the energy of the excited charge state is orders of magnitude bigger than the energy scales that the qubit operates at.

In order to initialize the qubit 201, the nuclear spins are first initialized followed by the electron spin (and simultaneously the charge state). The nuclear spin initialization itself requires repeated unloading and loading of electron spins, EDSR pulses, and qubit readout. However due to the extremely long nuclear spin lifetimes, this process need not be repeated frequently.

To initialize the nuclear spins, first their spin state needs to be established by nuclear spin readout. According to one setup, nuclear spin readout relies on probing the different EDSR transition frequencies of the electron spin, as the latter are dependent on the nuclear spin states. Thus, the nuclear spin readout needs to be performed in the two-dot regime. This has the additional benefit that the nuclear spins of both dots can then be readout simultaneously as the electron is coupled to the nuclear spins in both dots. The EDSR probing is to be performed at a static electric field value where none of the states of interest are degenerate, to allow establishing which nuclear spins need to be flipped.

Nuclear spin readout via EDSR is operated in a similar way as nuclear spin readout via ESR—i.e., a spin-down is loaded into the right dot 204 (into the |Rψ charge state). This charge and spin state is then adiabatically transferred to the chosen region in the hybridized regime. It will be appreciated that this transfer need not be adiabatic with respect to nuclear spins, but only reversible in that respect. In almost all cases, this is of no concern as the adiabaticity with respect to charge automatically guarantees adiabaticity with respect to both nuclear and electron spin. Once the state has been transferred to the hybridized regime, an EDSR burst probes the first of the possible EDSR transitions corresponding to a given nuclear spin configuration.

The qubit state is then measured through either spin or charge readout, depending on the chosen device setup. If it is in the electron spin up branch (with some excited charge state proportion if the readout is performed in the hybridized regime), the nuclear spins are indeed in that configuration, and the nuclear spin readout is finished. If the qubit state however is not in the spin up branch, the nuclear spin state is not in the configuration corresponding to the probed transition, and one needs to probe the next possible EDSR transition. This is repeated until the electron spin has been successfully flipped.

In practice, depending on the readout fidelity, every shot (electron initialization, transfer, EDSR burst and spin/charge readout) might need to be performed several times for high fidelity readout. This is possible because the nuclear spin readout is a quantum non-demolition (QND) measurement. Also, the EDSR burst will likely be performed by adiabatic inversion, as opposed to a coherent π-pulse, the former being more robust against variations in the EDSR driving strengths of different EDSR transitions.

Once the state of the nuclear spins has been established, a series of NMR pulses are performed to flip those nuclear spins that are not in the orientation of the nuclear state in which the qubit is to be initialized. Nuclear magnetic resonance control can be performed without the unpaired electron in the system provided the nuclear spin states are sufficiently non-degenerate. If some of the nuclear spin states are degenerate, NMR can be performed while an electron is loaded on the corresponding dot. The electron hyperfine interaction then mediates an interaction between the nuclear spins, which lifts the corresponding degeneracy. The NMR transition frequency is calibrated separately by performing NMR spectra for each respective case.

The electron spin can be initialized into the spin ground state |↓ [symbol] by first emptying the dot of the unpaired electron forming the qubit by tunneling to the reservoir (e.g., gate 206), and by subsequent spin selective tunneling of a fresh electron from the reservoir. By adjusting the Fermi-level of the electron reservoir in between the Zeeman split empty spin states, electrons spin down states in the reservoir have enough energy to populate the empty dot state, while spin up states do not. This process is routinely performed in semiconductor spin qubits. The tunnel rate of the electron to it reservoir needs to be tuned in such a way that single electron tunneling can be detected by a nearby charge sensor.

As described above, it can be advantageous to perform qubit manipulations on the same electron and nuclear spin state in either of the two orbital regimes (hybridized “two dot regime”, or pure spin “single dot” regime).

A transfer from the single dot regime to the hybridized regime can be performed with low errors using the third unpaired electron for a 2P-1P system. In such a system, the average hyperfine coupling of the electron to the left nuclei would be reduced to about [symbol] A_{L} [symbol] =10 MHz due to shielding from the inner shell electrons and the hyperfine coupling to the right nucleus would be close to the bare 1P coupling: A_{R}=117 MHz. The spectator hyperfine difference ΔA_{L} in the hyperfine coupling of the electron to the two nuclei in the left dot determines how closely the two states | [symbol] and | [symbol] are to being fully degenerate.

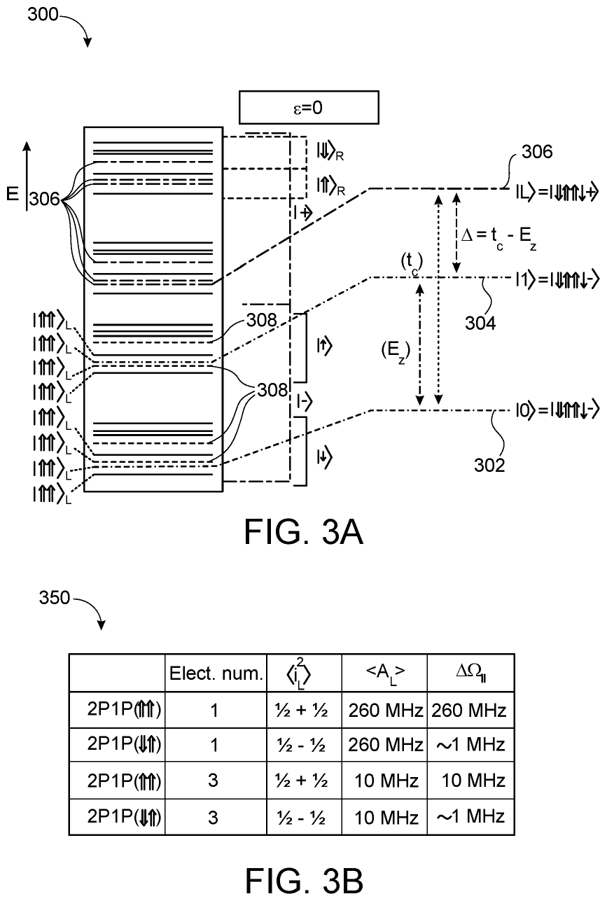

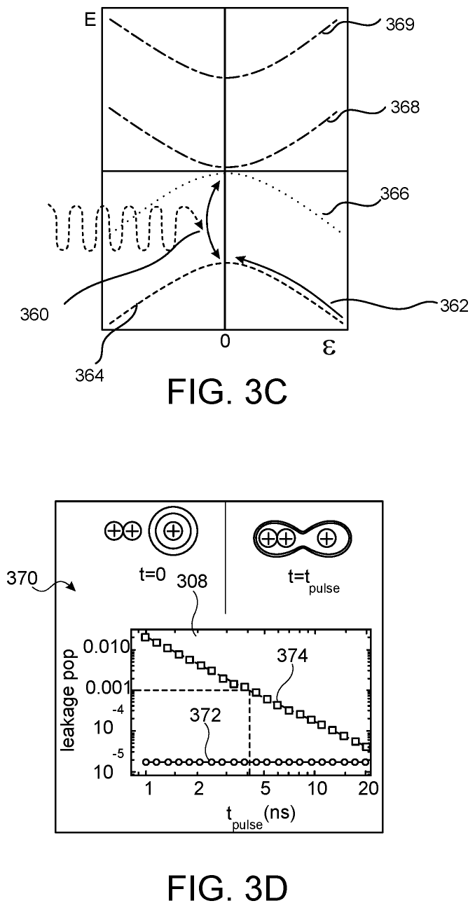

FIG. 3 illustrates the operation of the qubit 201 for an example 2P-1P donor-donor device 200. In particular, FIG. 3A shows the energy level diagram for the qubit 201 at zero detuning (ϵ=0). Due to total spin conservation under flopping mode operations, only a subset of the states in the hyperfine manifold need to be considered. The qubit states are defined as the states, |0 [symbol] =| [symbol] ↓− [symbol] 302 and |1 [symbol] =| [symbol] ↑− [symbol] 304. The charge state |− [symbol] is defined by the two quantum dot orbitals associated with the (3,0)↔(2,1) electron charge transition. The nuclear spins on the left quantum dot are initialized in the antiparallel state | [symbol] . For a 2P-1P donor-donor device, FIG. 3A shows the qubit states in 302 and 304. The left panel of FIG. 3A shows: low energy qubit state 302, the high energy qubit state 304, the nuclear spin leakage states 308 and the excited charge states |L [symbol] =| [symbol] ↓+ [symbol] 306. The remaining states can be neglected as they are outside of the chosen magnetization subspace [symbol] ₘ^{N}^{ₛ}⊗ [symbol] _{c} and cannot be leaked into during electric driving.

The (3,0)↔(2,1) electron transition is selected so that the additional electron spins on the 2P quantum dot form an inactive singlet-state that screen the hyperfine interaction of the nuclei in the core to the outermost electron spin.

The qubit 201 can be mathematically described by a similar Hamiltonian to the ones describing qubit 100 and qubit 120. Indeed using a Schrieffer-Wolff transformation, the exact Hamiltonian describing qubit 201 can be approximated to a Hamiltonian of the same form as the ones describing qubit 100 and qubit 120. This Hamiltonian has the following form, in terms of the transverse ΔΩ_{⊥} and longitudinal ΔΩ_{∥} gradients.

$$H = {Ω}_{z} {σ}_{z} + {ϵτ}_{z} + {t}_{c} {τ}_{x} + ( \frac{{ΔΩ}_{‖}}{2} {σ}_{z} + \frac{{ΔΩ}_{⊥}}{2} {σ}_{x} ) {τ}_{z} \qquad ( 3 )$$

In equation (3), the σᵢ(τᵢ) are the Pauli-operators for the combined electron-nuclear spin (charge) degree-of-freedom. The first term, Ω_{z} is the energy of the combined electron-nuclear spin state (which depends on the exact value of the left and right donor hyperfine, A_{L} and A_{R}). This energy can be found to be equal to Ω_{z}=\sqrt{Ωₛ²+A_{R}²/4}, where Ωₛ=(γₑ±γₙ)B₀+Σₖ^{N}^{_{L}}A_{L,k} [symbol] i_{L,k}^{z} [symbol] /4 is the Zeeman energy with a correction due to the hyperfine interaction of the electron with the nuclear spins in the left quantum dot and [symbol] i_{L,k}^{z} [symbol] is the expectation value of the z-projection of the k-th nuclear spin on the left quantum dot. The charge part of the Hamiltonian, H_{charge} is described by the second (detuning, ϵ) and third (tunnel coupling, t_{c}) terms of Eq. 3. The last term is the charge-dependent hyperfine interaction. The longitudinal and transverse gradient can be expressed as:

ΔΩ_{∥}=Σₖ^{N}^{_{L}}A_{L,k} [symbol] i_{L,k}^{z} [symbol] /2 cos θ−i A_{R} sin θ, (4)

ΔΩ_{⊥}=A_{R} cos θ−Σₖ^{N}^{_{L}}A_{L,k} [symbol] i_{L,k}^{z} [symbol] /2 sin θ, (5)

Where tan θ=A_{R}/2Ωₛ. Since typically Ωₛ>5 GHz is much greater than A_{R}≈100 MHz, sin θ≈0 and cos θ=1 then ΔΩ_{∥}≈Σₖ^{N}^{_{L}}A_{L,k} [symbol] i_{L,k}^{z} [symbol] /2 and ΔΩ_{⊥}≈A_{R}.

This means that the longitudinal energy gradient, ΔΩ_{∥} k can be controlled by the magnitude of A_{L} during fabrication by the number of the donor atoms in the quantum dot 202, and during qubit operation by the z-projection of the nuclear spins on the left quantum dot 202 by nuclear magnetic resonance (NMR) or dynamic nuclear polarization (DNP).

FIG. 3B shows a table of different nuclear spin and electron configurations (which define the average donor hyperfine magnitude A_{L}) and the effect of these configurations on the value of the longitudinal energy gradient Ω_{∥}. As shown in this figure, control of the donor hyperfine magnitude A_{L} and nuclear spin orientations ( [symbol] i_{L}^{z} [symbol] ) allows tuning of the hyperfine coupling values and longitudinal energy gradient ΔΩ_{∥}.

In general, as the number of donors in a quantum dot is increased, the hyperfine strength of the electron becomes larger. This is useful for increasing the transverse magnetic field gradient required for qubit driving and can make the hyperfine interaction significantly different between the quantum dots. However, this effect also makes the longitudinal magnetic field gradient larger. To counter this effect, the quantum dot may be filled with more electrons to create a shielding effect of the outer electron to the donor nuclear spins which results in a reduced hyperfine coupling. In the case of a single donor coupled to a 2P quantum dot (2P-1P) at the (2,1)↔(3,0) charge transition so that the two inner electrons on the 2P quantum dot lower the hyperfine interaction of the outermost electron while the use of two nuclear spins means that we can initialize them in an antiparallel state further reducing the hyperfine coupling.

FIG. 3C shows the four main branches of the energy spectrum of a single electron orbiting two quantum dots coupled by a tunnel coupling t_{c}, as a function of the electric detuning between the two quantum dots, in a fixed magnetic field. There is shown adiabatic qubit driving 360 and qubit initialization 362. The four branches of the energy spectrum represent the lowest qubit state 364, the highest qubit state 366, and the excited states 368 and 369.

Excited charge state leakage is present in any of the flopping-mode EDSR based qubits due to hybridisation of charge and spin. The first possibility of leakage is during the adiabatic ramp to ε=0 to initialise the qubit. For |ϵ|>>t_{c} there is no charge-like component of the qubit 201 and the ground state can be initialised by loading a |↓ [symbol] electron from a nearby electron reservoir. The nuclear spins can also be initialised via NMR or dynamic nuclear polarisation to place the nuclear spin in the | [symbol] state. Next, the detuning is ramped to ε=0 to initialise the |0 [symbol] qubit state (see FIG. 3C). During the ramp the qubit can leak out of the computational basis via charge excitation into the excited charge state or through unwanted nuclear spin flips.

FIG. 3D shows the simulated leakage probability for both of the leakage pathways (nuclear spin flips 372 and charge excitations 374) during the initialisation ramp as a function of ramp time for a 2P1P (3 electron) system with t_{c}=5.6 GHz, ΔA_{L}=|A_{L,1}−A_{L,2}|=1 MHz and B₀=0.23 T. It can be seen from the figure that regardless of the initialisation pulse time, tₚ the leakage into the excited charge states is the dominant pathway. This mechanism exists for all flopping-mode EDSR based qubits due to the non-adiabaticity of the initialisation pulse. By ramping slow enough we can initialise the qubit at ε=0 starting at ε=110 GHz with an error of 10⁻³ in a tₚᵤₗₛₑ=4 ns ramp dominated by the charge leakage. The nuclear spin leakage does not depend heavily on the pulse time and remains well below the charge leakage with an error of ˜2×10⁻⁵. Therefore, it can be concluded that the nuclear spin state leakage is not a limiting factor in the initialisation of the qubit 201.

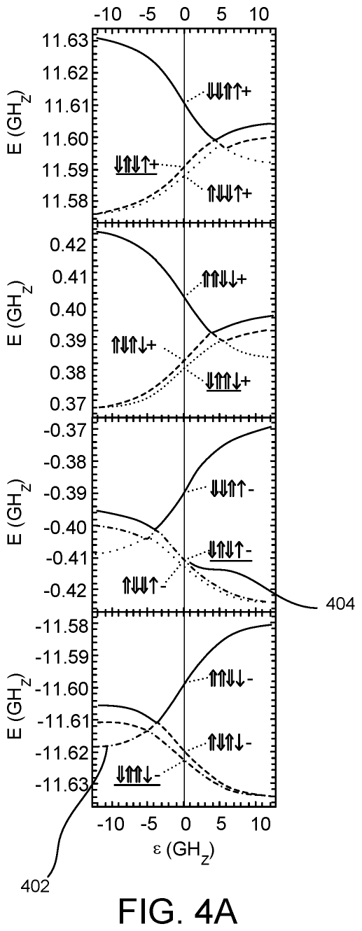

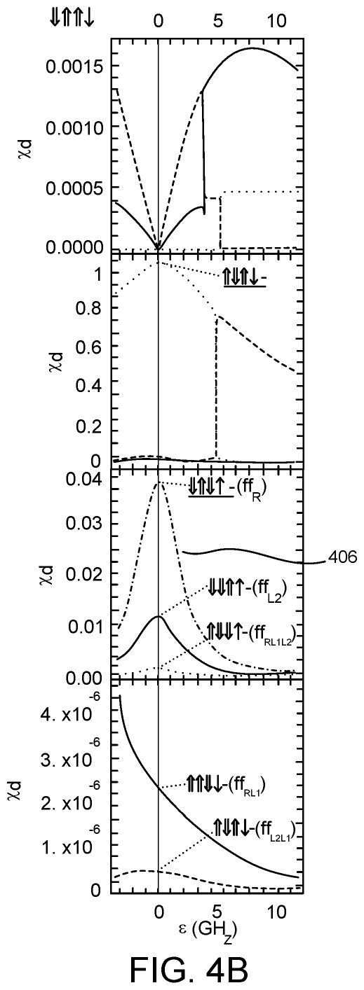

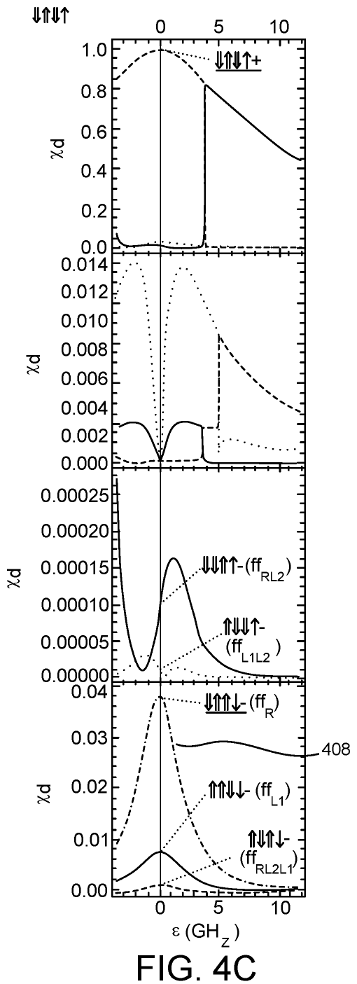

FIG. 4 illustrates the energy levels of a 2P-1P system 200, and the dipole coupling strengths between each qubit state and the other states. In particular, FIG. 4 illustrates the eigenstate energies E and their electric dipole couplings μ_{d}. The system parameters are B=0.4 T, t_{c}=6.0 GHz, ΔA_{L}=10 MHz, A_{L}=30 MHz, and A_{R}=117 MHz. Well-separated hyperfine values were used for clarity. FIG. 4A is a schematic of the eigenstate energies E where the electric field dependency of the bare charge qubit has been subtracted for clarity. The qubit ground and excited states are depicted by first and fifth eigenstate energies at ϵ=0 (see 402 and 404 in FIG. 4A). FIGS. 4B-4C are schematics showing ground/excited state dipole coupling coefficients. The dipole-coupling coefficient between the two-qubit states is depicted by 406 and 408 in FIGS. 4B and 4C, respectively. The dipole coupling coefficient for the pure charge transitions reach unity at ϵ=0 (third and fourth frame from the bottom, for the ground/excited state respectively.)

In FIG. 4A, the ground/excited charge state branch is displayed in the two lower/higher plots in the figure and are split by the charge qubit splitting Ω_{c}=2(\sqrt{∈²+t²}). The charge qubit is defined by the orbital levels of the left and right quantum dots and at ϵ=0, the qubit states are |− [symbol] =(|L [symbol] −|R [symbol] )/\sqrt{2} and |+ [symbol] =(|L [symbol] +|R [symbol] )/\sqrt{2}. The spin down/up branches are further subdivided into separate plots. Each subplot thus displays the three possible nuclear spin configurations or same magnetization, for electron and charge states |↓− [symbol] , |↑− [symbol] , |↓+ [symbol] and |↑+ [symbol] , from bottom to top in ascending energy. The qubit ground and excited state |g(ϵ) [symbol] ≈| [symbol] ↓− [symbol] and |e(ϵ) [symbol] ≈| [symbol] ↑− [symbol] energies, are very close in energy to their near degenerate states | [symbol] ↓− [symbol] and | [symbol] ↑− [symbol] respectively.

For high detuning values ϵ, the eigenstates asymptotically approach the single dot regime, where the ground charge state |− [symbol] is the right dot orbital |R [symbol] , the spins are not hybridized to charge, and no higher order coupling between the degenerate states is present. When approaching ϵ=0, the right dot orbital state hybridizes into an antisymmetric superposition with the other dot orbital. At the same time a higher order coupling weakly couples the degenerate states in the electron spin-up branch.

The second possibility for leakage is during single-qubit gate operations. As discussed previously, FIG. 3A shows the full energy spectrum of the donor-donor implementation at zero detuning, ε=0. On the right, the figure shows the qubit states (302 and 304) and the charge leakage state (306) with their relative energies. There are 32 spin and charge states in the full system and leakage into all possible nuclear spin states is considered during driving. There are two types of leakage errors due to the nuclear spin states. These two leakage errors are critical for nearly degenerate hyperfine values between the different nuclear spins, A_{L,k}≈A_{R} for example with a 1P-1P system. The first leakage pathway is due to unwanted electron-nuclear transition of the left nuclear spins and is proportional to (A_{L}/A_{R})², such as the transition | [symbol] ↓− [symbol] →| [symbol] ↑− [symbol] . Therefore, it is optimal to make A_{L}<<A_{R} to limit the unwanted flip-flop events by creating asymmetric donor-based quantum dots. The second leakage process involves a simultaneous electron-nuclear flip-flop with all three of the nuclear spins (for example, | [symbol] ↓− [symbol] →| [symbol] ↑− [symbol] and requires that there is a difference in energy between the left quantum nuclear spins ΔA_{L}>0. The value of ΔA_{L} is unlikely to be zero due to the presence of electric fields in a real device and so this leakage pathway should be easily avoidable. Well-designed pulses have minimised leakage out of the qubit subspace by effectively adiabatically reversing the leakage process. In particular, a Gaussian pulse shape may be used to partially reverse the leakage process due to charge and nuclear spins during qubit operation.

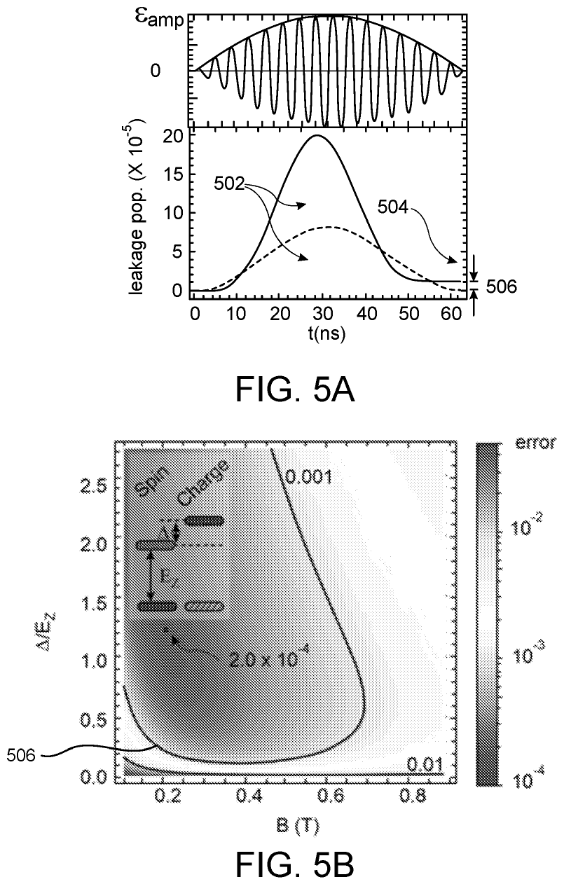

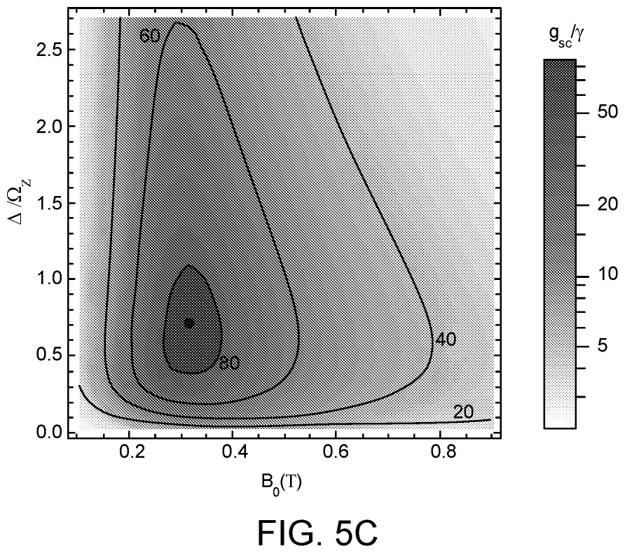

FIG. 5A shows two leakage populations during π/2−X Gaussian pulse for the donor-donor qubit using optimal parameters for this device: drive amplitude=0.9 GHz, B₀=0.23 T and t_{c}=5.6 GHz. Reversible leakage is depicted 502 and irreversible leakage is shown 504.

To investigate the qubit performance the qubit error for a π/2−X gate as a function of magnetic field and tunnel coupling including sources of noise: pure spin/charge dephasing, drive errors, charge relaxation, and idle qubit relaxation is shown in FIG. 5B. Importantly, the gate error remains low (<10⁻³) over a wide range of magnetic fields and tunnel couplings. The wide operational parameter space is crucial in a large-scale architecture where small uncertainties during fabrication can lead to variation in the qubit-to-qubit performance. By optimizing the magnetic field and tunnel coupling we can achieve a minimum gate error of 2×10⁻⁴ well below the surface code fault-tolerant threshold with realistic noise. The low magnitude of the longitudinal gradient engineered in this qubit is crucial to obtain this low qubit error and the wide operational parameter space.

Purely electric control of the qubit 201 is made possible by using the artificial SOC in the hybridized two-dot regime. When driving the electric field at the qubit frequency, the qubit can be coherently driven into any superposition of the ground and excited qubit states. The frequency is given by ν_{QB}=E_{QB}/h, where h is the plank constant and E_{QB} is the energy between the qubit ground and excited states. Making this hybrid spin qubit addressable electrically has the advantage of being much more power efficient than driving a spin qubit magnetically. It also allows strong coupling of two distant qubits via electrostatic coupling (direct, or mediated by a floating gate, or even a cavity). The drawback of electrical control is that the qubit is made sensitive to electrical noise and charge relaxation. Charge relaxation arises from the interaction between the charge qubit and the environment, and results in a projection into the charge ground state that gets exponentially more probable with time. Magnetic noise in semiconductors is primarily linked to fluctuations in the orientations of magnetic nuclear spin species. In silicon and germanium, magnetic noise can be reduced by about three orders of magnitude by isotopically purifying the material in order to eliminate the magnetic fluctuations. This makes electric noise the principal noise source in those isotopically purified materials.

To obtain the required inter-qubit coupling faster than the dephasing time (on the order of a few MHz) up to three different coupling schemes can be utilized. These are outlined below.

For a fully realized surface-code algorithm, it is necessary to perform two-qubit entangling gates between neighboring qubits. The electric dipole interaction from the charge character of the proposed qubit allows for fast, high-fidelity two-qubit gates over medium distances (which can be extended via floating gates) and long-distance gates via superconducting cavity resonators. The electric dipole of an electron moving between two quantum dots separated by d is given by,

μ=ed. (6)

It can then be shown that dipole-dipole coupling Hamiltonian between two dipoles separated by a distance r is given by,

H_{dd}=V(σ_{z,1}σ_{z,2}+σ_{z,1}+σ_{z,2}), (7)

Where σ_{z,i} the pauli-z operator for qubit i and

$$V = Γ \frac{- 2 {μ}_{1} {μ}_{2}}{4 π h {ϵ}_{0} {ϵ}_{r} {r}^{3}} \qquad ( 8 )$$

The parameter Γ is a geometric correction that depends on the orientation of the dipoles relative to each other and is ¼ for the planar geometry and 1 for the vertical qubits. Finally, ϵ₀ is the permittivity of free space and ϵᵣ the relative permittivity of silicon, 11.7.

The two-qubit coupling of the charge degree-of-freedom of the qubits is given by,

$${g}_{2 c} = V \frac{{t}_{1} {t}_{2}}{{Ω}_{1} {Ω}_{2}}$$

Where tᵢ is the tunnel coupling of qubit i and Ωᵢ is the charge state splitting. This dipolar coupling can be as large as a few GHz depending on the separation between the qubits. The relative strength of the qubit-qubit coupling can be controlled by varying the amount of charge character of the EDSR qubit. Therefore, qubit separations of a few 100 nm are possible.

Further, the dipolar coupling can be significantly increased by using a floating gate electrode between the two qubits allowing for qubit separations of about a few microns.

The use of superconducting cavities can also significantly extend the coupling distance of the two qubits. In this scenario, both qubits are coupled to the cavity with a frequency, ν with a coupling strength given by,

$${g}_{sc} = \frac{{eE}_{rms} d}{4 h} \frac{t}{Ω} \qquad ( 9 )$$

where Eᵣₘₛ is the root-mean-square electric field fluctuations of the cavity.

The superconducting cavity coupling operates over the length scale of a few millimeters and can be used outside of the qubit array to couple the outer qubits of one qubit array to corresponding outer qubits of another array. This large distance is useful for additional classical electronics that may need to be incorporated onto the quantum computing chip for large scale computing function.

FIG. 5C shows a simulation of the expected ratio of the spin-cavity coupling strength, g_{sc}, to the qubit dephasing rate, γ, for an optimized 2P-1P qubit with ΔΩ_{∥}=0.5 MHz by initializing the nuclear spin in antiparallel states and using three electrons shared between the two donor clusters. The quantity g_{sc}/γ is plotted against the static magnetic field B₀ and the relative spin-charge detuning Δ/Ω_{z}, where the spin-charge detuning Δ is equal to Δ=2t_{c}−Ω_{z}, at ϵ=0, and Ω_{z} is the spin-qubit energy.

The spin-cavity coupling strength, g_{sc}, is calculated numerically assuming realistic cavity electric detuning amplitudes ϵ_{c}=100 MHz.

The dephasing rate γ is calculated by converting the π/2−X gate error probability e_{π/2} into a coherence time based on the optimal π/2 gate time t_{π/2} for each value of t_{c} and B₀. The formula describing the dephasing rate is:

$$γ = \frac{1}{2 \sqrt{2}} \frac{\sqrt{Log ( \frac{1}{1 - 2 {e}_{π / 2}} )}}{{t}_{π / 2}} .$$

Further, FIG. 5C shows that the qubit dephasing rate itself is smaller than the spin-cavity coupling for all values of t_{c} and B₀ shown. This is a requirement for achieving strong coupling of the qubit to the superconducting cavity, and indicates that the qubit coherence is not the limiting factors in achieving the strong coupling regime.

In order to achieve strong qubit-cavity coupling, g_{sc} also needs to be faster than the decay rate of the cavity: g_{sc}/κ>1. The quality of the coupling of the qubit to the cavity is then characterized by the cooperativity: C=g_{sc}²/γκ, that needs to be larger than one. Assuming a realistic cavity decay rate of κ=1 MHz, these simulations show that the qubit can reach a cooperativity of up to 130 while maintaining an error below 0.1%. This cooperativity value is achieved while satisfying g_{sc}/κ=2.7>1.

### Large Scale Architecture

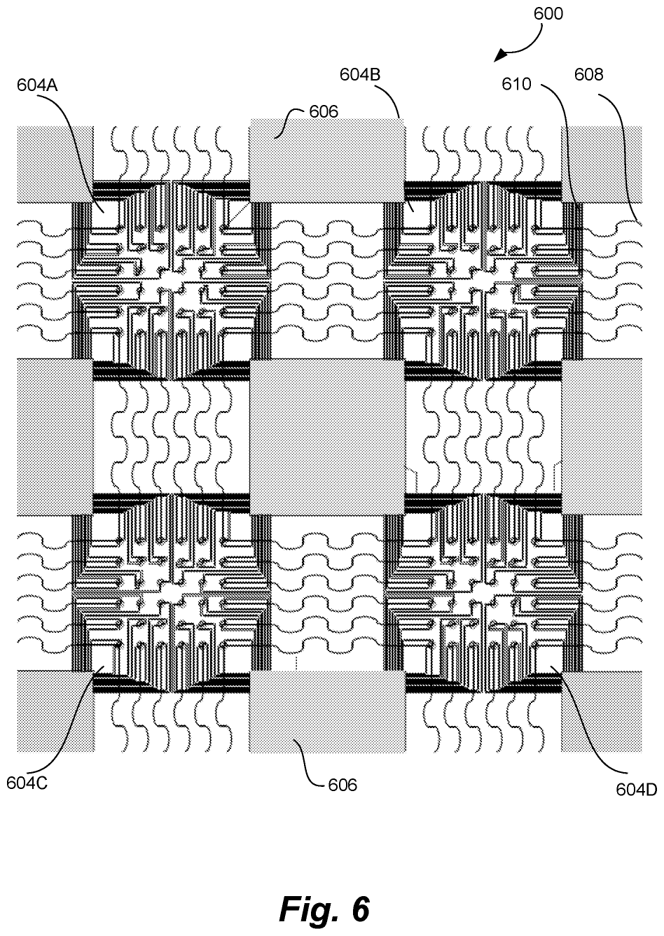

FIG. 6 illustrates an example large scale architecture 600 formed of one or more of the flopping mode qubits described previously. In particular, the qubit architecture 600 includes a two-dimensional square lattice of qubits in which the nearest neighbor qubits are coupled via either dipole couplings or superconducting resonators/cavities.

As seen in FIG. 6, the qubits are concentrated in square nodes 604A-604D, with each node including a plurality of qubits arranged in a grid. In each node, the nearest neighbor qubits are coupled via a short-range interaction (such as dipole coupling or floating gate coupling). The edge qubits of each node 604A-604D are coupled to nearest neighbor edge qubits of a neighboring node 604 via superconducting resonators 608.

Qubit control and readout is performed via metallic gates 610 that connect the greyed out interstitial spaces 606 (or interstitial nodes as referred herein) between nodes 604 to each qubit (two gates per qubit in this particular case). The interstitial nodes 606 include some classical control and readout electronics, as well as interconnects to higher layers of different chips altogether (for example with the “flip-chip” technique or using bond wires).

In certain embodiments, the readout signals are multiplexed so that only a few RF lines are wired to each interstitial node, and resonators of non-overlapping frequencies (superconducting or not) patterned within that space allow addressability of each qubit. The drive microwave electric drive signals as well as DC control signals are also routed to their respective qubit within this space.

Furthermore, in some implementations, DC control signals are multiplexed using dynamic random-access memory (DRAM) like technologies, allowing for several DC lines running from the cold finger of the dilution fridge refrigerator to each interstitial space to scale much more advantageously with the number of qubits.

Assuming each node has N² qubits, 2N bit and word lines are needed to address each qubit individually. The control and readout of the bit and word lines can be performed off-chip (in which case 2N DC lines are routed for each node) or on-chip using binary multiplexing.

For binary multiplexing, the bit and word lines are addressed digitally, and the number of lines routed to each interstitial node is log₂(2N). In other words, the number of DC lines routed to each interstitial node either as the square root of the number of qubits, or even logarithmically with the square root of qubits, depending on the addressing technique used (multiplexing or not).

As binary multiplexing circuits have high heat output, it may not be possible to place these circuits on chip, and these circuits may be placed at a different stage of the dilution refrigerator, providing more cooling power. However, the low refresh rate needed for the slow DC biasing might be compatible with on-chip operation.

The DC, readout (RF or MW) and drive (MW) signals are routed to the respective qubit control lines using bias tees (preferentially lithographically patterned). In case each qubit is addressed by two gates, the readout and drive signals are separated to avoid additional complexity.

The complexity of routing the control lines from the interstitial nodes to the qubits within the nodes depends on the number of qubits within the nodes and on the spacing between neighboring qubits. The spacing between qubits, and the available pitch of the lithographic method used informs the number n_{L} of leads one can route between existing qubits. With existing lithographic techniques, a 40 nm pitch for 10 nm wide leads is achievable. For the microwave lines, the pitch might be increased due to the need to design the lead as a coplanar waveguide to improve the transmission of the signals. The distance between qubits is of the order of 200 nm for dipole-coupled qubits, whereas it could be of the order of ≈2 μm for the floating gate coupling mechanism. This would allow about n_{L}≈4 for dipole-coupled qubits, and n_{L}≈50 for floating gate coupled qubits.

For a small number (N²) of qubits, and a high number n_{L} of possible leads between qubits, a gate can be routed to every qubit using a single lithographic plane. Such a single layer routing is shown in FIG. 6 for 36 qubits (N=6) per node 604, two gates per qubit, and 4 possible feedthroughs between each qubit pair (n_{L}=4). The number of lithographic layers needed to address N² qubits with several n_{L} possible feedthroughs can be determined between adjacent qubits by:

$${n}_{lith layers} \approx \frac{N}{2 {n}_{L} + 3} \qquad ( 10 )$$

In the example of dipole coupled qubits within each node (where n_{L}≈4), a single gate can be routed to all qubits of a node of 324 qubits (N=18) in a single lithographic layer, and 841 qubits (N=29) using a two-layer lithographic stack of leads.

In the case of qubits coupled by ≈2 μm long floating gates, and assuming the extra convenience of having two gates per qubit meaning that n_{L} is effectively reduced from 50 to 25, 10404 qubits (N=102) can be wired using a single lithographic layer, and 27225 qubits (N=165) can be wired using a two-layer lithographic stack of leads.

Tables 2 and 3 summarize the maximum number of qubits (QBs) that can be routed with leads in one or two lithographic layers for the two different kinds of couplings, for the case of a single lead per qubit and a pair of lead per qubit, respectively

TABLE 2
Single lead per qubit numbers

| | dipole | | floating gate |
|---|---|---|---|
| n_{lith layers} | 1 | 2 | 1 |

| | | |
|---|---|---|
| d_{NN} | 200 nm | 2 μm |

| Qubit density (μm⁻²) | 28 | | 0.25 |
|---|---|---|---|
| n_{L} | 4 | | 50 |
| Nₘₐₓ | 18 | 29 | 202 |
| max number of Qubits | 324 | 841 | 40 804 |
| Node area | 12 μm² | 31 μm² | 0.1 mm² |

TABLE 3
double lead per qubit numbers

| | dipole | | floating gate |
|---|---|---|---|
| n_{lith layers} | 1 | 2 | 1 |

| | | |
|---|---|---|
| d_{NN} | 200 nm | 2 μm |

| Qubit density (μm⁻²) | 28 | | 0.25 |
|---|---|---|---|
| n_{L} | 2 | | 25 |
| Nₘₐₓ | 10 | 17 | 102 |
| max number of Qubits | 100 | 289 | 10 404 |
| Node area | 3.2 μm² | 10 μm² | 0.04 mm² |

As seen in tables 2 and 3, the achievable qubit numbers are significantly higher for the floating gate implementation compared to the dipole one. This is because the number of qubits possible in one node scales as n_{L}². However, it is noted that the qubit density is 100 times higher for the dipole-coupled qubits.

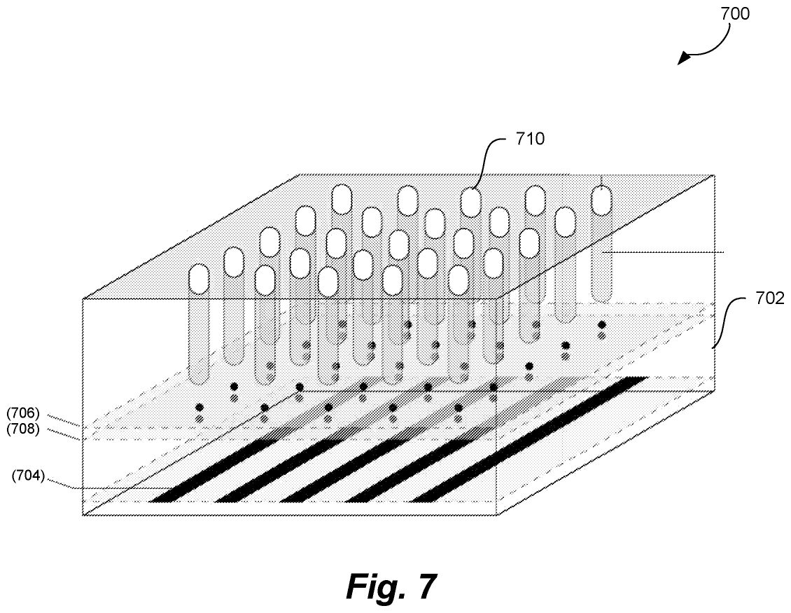

FIG. 7 illustrates an example implementation of a node architecture 700 for qubits coupled using dipole coupling. In one example, node 700 is any one of the nodes 604A-604D of FIG. 6.

As seen in FIG. 7, the node 700 includes a silicon substrate 702. Control lines 704 are patterned into the silicon substrate 702 in one plane. The control lines 704 may be patterned in parallel to each other. Further, the node includes two quantum dot layers 706, 708. Each quantum dot layer includes a number of quantum dots formed by patterning donor clusters. The donor atom clusters may be formed such that the position of the cluster corresponds with a control line patterned in the layer below the quantum dot layers. The number of donor atoms per donor cluster determines the type of qubit. For instance, if one layer of quantum dots includes one donor atom per donor cluster and another layer includes two donor atoms per donor cluster, a 2P-1P qubit is generated.

The node further includes a plurality of metallic contacts 710 pattered on the surface of the silicon substrate 702, such that each metallic gate is positioned above a corresponding qubit. Drive and readout is performed via the metallic contacts above each qubit.

In this example, the node 700 includes 25 qubits. The dipole-dipole coupling between two neighboring qubits is proportional to the scalar product of their respective dipole moments. The dipole moment is oriented along the axis separating the two quantum dots of each qubit. In this embodiment, the qubits are patterned so that the dipole moments are parallel allowing maximal nearest neighbor coupling between all qubits in two dimensional surface code square lattice. Each donor cluster pair forming a qubit would thus be patterned within the silicon lattice using one of two separate hydrogen lithography steps.

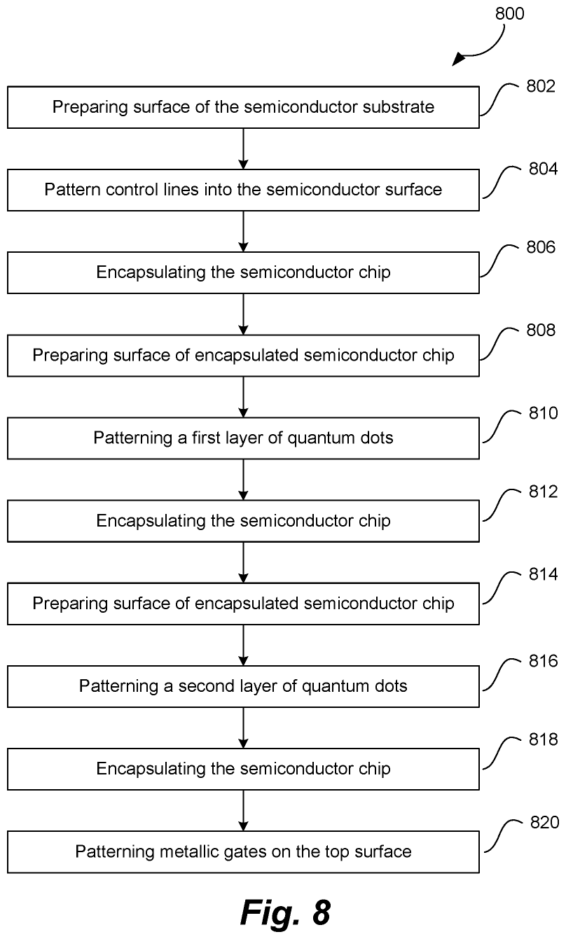

FIG. 8 is a flowchart illustrating an example manufacturing procedure for each node 600. It will be appreciated that the nodes of a quantum computer can be manufactured in parallel, with all infrastructure in each lithographic layer finalized, before manufacturing the next layer. FIG. 8 describes a process for manufacturing a node 600 including one or more 2P-1P flopping mode qubits. It will be appreciated that this is just one example, and the process can be implemented to manufacture any nP-mP flopping mode qubits 201.

At step 802, the surface of a semiconductor substrate is prepared. In case the substrate is ²⁸Si this step includes forming a clean silicon substrate surface in an ultra-high vacuum (UHV) by heating to near the melting point. This surface has a 2×1 unit cell and consists of rows of σ-bonded Si dimers with the remaining dangling bond on each Si atom forming a weak π-bond with the other Si atom of the dimer of which it comprises.

The clean silicon substrate surface is then exposed to atomic hydrogen to break the weak silicon π-bonds, allowing hydrogen atoms to bond to the Si dangling bonds. Under controlled conditions, a monolayer of hydrogen can be formed with one hydrogen atom bonded to each silicon atom, satisfying the reactive dangling bonds, effectively passivating the surface.

Next at step 804, a first layer of control lines 704 is patterned into the silicon substrate. In one example, the control lines are Si:P lines in parallel and the control lines 704 may be patterned using STM lithography. Further, one control line 704 may be manufactured for each column of qubits within each node.

Next, at step 806, the semiconductor chip is encapsulated with a layer of ²⁸Si. The layer of ²⁸Si may be a few 10 s of nm. In one example, the semiconductor chip is encapsulated using state of the art molecular beam epitaxy. This step is called the first encapsulation.

At step 808, the surface of the encapsulated semiconductor substrate is prepared. This is similar to the process of step 802. However, this step and all following surface preparation steps are performed at lower temperatures to avoid diffusion of the dopants patterned below.

Thereafter, at step 810, a first quantum dot layer is patterned into the silicon substrate. In particular, the first quantum dot layer is patterned to include one donor cluster per qubit. In some examples, an STM tip is used to selectively desorb H atoms from the passivated surface by the application of appropriate voltages and tunneling currents, forming a pattern in the H resist. In this way, regions of bare reactive silicon atoms are exposed, allowing the subsequent adsorption of reactive species directing to the silicon surface. Phosphine gas is introduced to the silicon surface via a controlled leave valve connected to a specifically designed phosphine micro-dosing system. The phosphine molecules bond strongly to the exposed silicon surface, through the holes in the hydrogen resist. Subsequent heating of the STM patterned surface for crystal growth causes the dissociation of the phosphine molecules and results in the incorporation of P into the layer of silicon. It is therefore the exposure of an STM patterned H passivated surface to PH₃ that is used to produce the required P array.

Again, after phosphorus incorporation, at step 812, the silicon substrate is grown by about 10 nm-20 nm, to achieve the desired tunnel coupling between the quantum dot in the previous layer and the one in the next layer. This is called the second encapsulation.

Next, at step 814, the surface of the silicon substrate is once again prepared in a manner similar to that described with respect to step 808.

At step 816, the second quantum dot layer containing one donor cluster per qubit is patterned into the passivated silicon substrate in a manner similar to that described with respect to step 810.

Each donor cluster in the second quantum dot layer is tunnel-coupled to a corresponding cluster of the previous layer.

After phosphorus incorporation, at step 816, the silicon substrate is grown by about 20 to 50 nm. This is called the final encapsulation, which finalizes the STM UHV process.

After a final surface preparation, using standard lithography techniques (e.g., e-beam lithography or optical lithography), one or two metallic gates are patterned per qubit on the top silicon surface. As discussed in the previous section the routing of the leads from the interstitial nodes to the qubit gates may require several layers of metallic layers, separated from each other using insulating layers of high dielectric constant (for example SiO₂ or HfO₂). This is a well-known procedure within the semiconductor industry (for MOSFET or DRAM device for example).

It will be appreciated that the thickness of the layers and the distances between layers described in method 800 are merely exemplary. The actual thickness of layer and distances between layers will depend on chosen cluster sizes, electron numbers, and chosen static magnetic field value for the quantum computer.

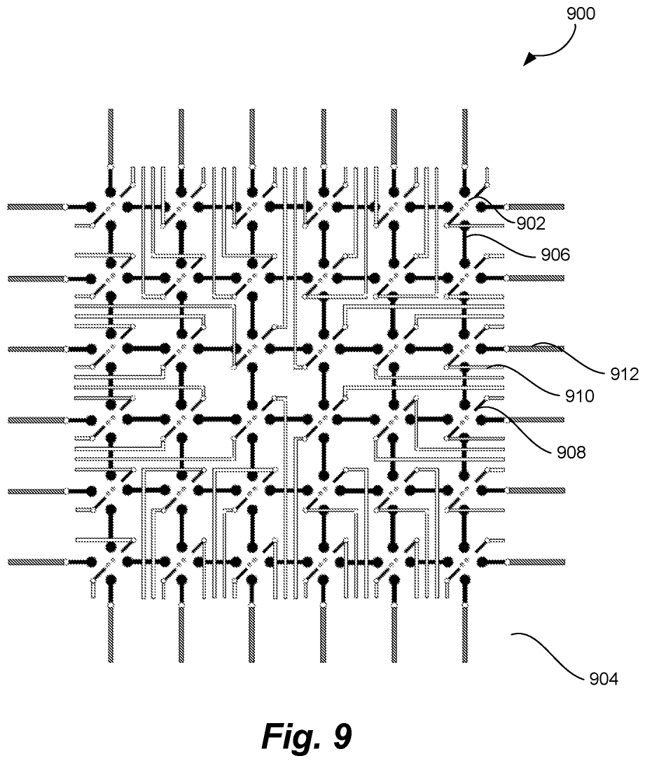

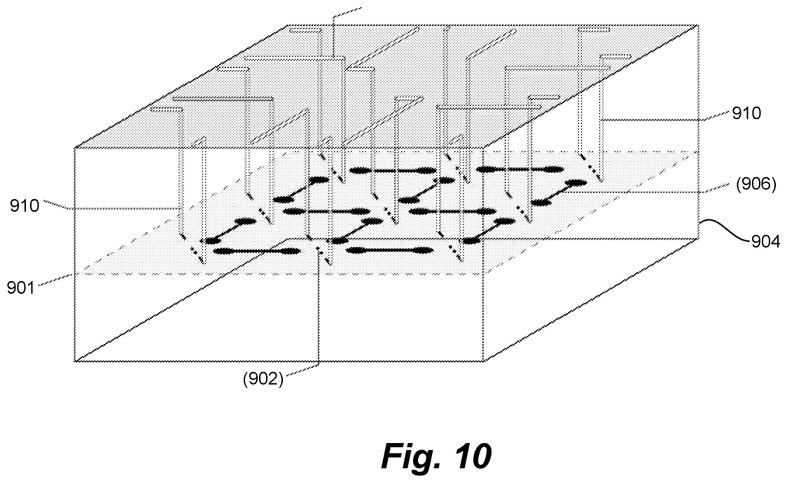

Another implementation of a node architecture for qubits coupled using floating gates is shown in FIGS. 9 and 10. In particular, FIG. 9 illustrates a top view of the node architecture 900 and FIG. 10 illustrates a side view of the node architecture.

In this example, the qubits 902, represented by a pair of dots, are patterned in the same lithographic plane, inside a crystalline isotopically purified silicon (²⁸Si) 904.

Each nearest neighbor qubit pair is coupled via floating gates (which can be elongated metallic islands) 906, represented by black structures in the form of a dog bone in the figures. Electrostatic control, drive and readout of each qubit 902 are performed via one or two gates 908. These gates 908 are connected to metallic leads 910.

The floating gates 906 enable spacing of up to a few micrometers between qubits allowing for multiple feedthroughs of metallic leads between them. In this way, a larger number of qubits can be addressed by leads within a single lithographic layer. However, the qubit density within the nodes 900 is reduced by about one order of magnitude when compared to dipole coupling shown in FIG. 7.

The “floating gates” at the outer perimeter of the node are not floating but connected to superconducting resonators 912. This allows long distance coupling of those qubits to their distant nearest neighbors in the next node(s).

Note that the floating gates 906 and control/readout/drive gates 908 can be manufactured either in the qubit plane, or on the silicon surface above. It is however advantageous to have both these types of gates patterned at the qubit plane. Indeed, this increases the capacitive coupling between the gates and the dots, and allows for stronger qubit-qubit coupling, qubit driving, better readout signal, and more electrostatic control.

The methods and the quantum processor architectures described herein uses quantum mechanics to perform computation. The processors, for example, may be used for a range of applications and provide enhanced computation performance, these applications include: encryption and decryption of information, advanced chemistry simulation, optimization, machine learning, pattern recognition, anomaly detection, financial analysis and validation amongst others.

1. A quantum bit comprising:
a first quantum dot embedded in the semiconductor substrate, the first quantum dot comprising a first donor atom cluster;
a second quantum dot embedded in the semiconductor substrate, the second quantum dot comprising a second donor atom cluster,
wherein the first and second quantum dots share an electron; and
wherein the quantum bit is electrically controlled based on hyperfine interaction between the electron and one or more nuclear spins present in the first and/or second donor atom clusters.

2. The quantum bit of claim 1, wherein an external static electric and magnetic field is applied to the quantum bit to enable spin of the electron to hybridize with the electron's orbital wave function.

3. The quantum bit of claim 1 or 2, wherein the one or more nuclear spins present in the first and/or second donor atom clusters are initialized to minimize a longitudinal energy gradient of the quantum bit.

4. The quantum bit of claim 3, wherein the first donor atom cluster includes an even number of atoms, and the second donor cluster includes an odd number of atoms.

5. The quantum bit of any one of claims 1-2, wherein:
loading one or more electron pairs on the first and/or second donor atom clusters causes a decrease in strength of the hyperfine interaction and a reduction in a longitudinal energy gradient of the quantum bit; and
unloading the one or more electron pairs from the first and/or second donor atom clusters causes an increase in the strength of the hyperfine interaction to increase a transverse energy gradient of the quantum bit.

6. The quantum bit of any of the preceding claims, wherein the first and second quantum dots are separated by an inter dot separation of about 10 to 20 nm.

7. The quantum bit of any one of the preceding claims, wherein the first donor atom cluster includes two donor atoms, and the second donor atom cluster includes one donor atom.

8. The quantum bit of claim 7, wherein the donor atom of the second donor atom cluster is initialized with a nuclear spin up.

9. A quantum processing element, comprising:
a semiconductor substrate and a dielectric material forming an interface with the semiconductor substrate;
a quantum bit comprising: a first quantum dot embedded in the semiconductor substrate and comprising a first donor atom cluster, a second quantum dot embedded in the semiconductor and comprising a second donor atom cluster, the first and second quantum dots sharing an electron;
one or more gates for controlling the quantum bit;
wherein the quantum bit is tuned such that the electron spin hybridizes with the electron's orbital wave function, allowing electric control of the quantum bit.

10. The quantum processing element of claim 9, wherein an external static magnetic and electric field is applied to the quantum processing element to enable the electron spin to hybridize with the electron's orbital wave function.

11. The quantum processing element of any one of claims 9-10, wherein one or more nuclear spins present in the first and/or second donor atom clusters are initialized to minimize a longitudinal energy gradient of the quantum bit.

12. The quantum processing element of claim 11, wherein the first donor atom cluster includes an even number of atoms, and the second donor cluster includes an odd number of atoms.

13. The quantum processing element of any one of claims 9-12, wherein
loading one or more electron pairs on the first and/or second donor atom clusters causes a decrease in strength of the hyperfine interaction and a reduction in a longitudinal energy gradient of the quantum bit; and
unloading the one or more electron pairs from the first and/or second donor atom clusters causes an increase in the strength of the hyperfine interaction to increase a transverse energy gradient of the quantum bit.

14. The quantum processing element of any one of claims 9-13, wherein the quantum bit is embedded in the semiconductor substrate a pre-defined distance below the interface.

15. The quantum processing element of claim 14, wherein the pre-defined distance is greater than 20 nm.

16. The quantum processing element of any one of claims 9-15, wherein the first and second quantum dots are separated by an inter-dot separation of about 10 to 20 nm.

17. The quantum processing element of any one of claims 9-16, wherein the donor atom cluster of one of the two quantum dots includes one donor atom and the donor atom cluster of the other of the two quantum dots includes two donor atoms.

18. The quantum processing element of claim 17, wherein the donor atom cluster that includes the one donor atom is initialized with a nuclear spin up.

19. The quantum processing element of any one of claims 9-18, wherein the donor atoms are phosphorous atoms, and the semiconductor substrate is a silicon substrate.

20. The quantum processing element of any one of claims 9-19, wherein the one or more gates are fabricated within the semiconductor substrate to control the donor clusters of the two quantum dots.

21. The quantum processing element of claim 20, wherein the one or more gates are manufactured in the same plane as the quantum bit.

22. The quantum processing element of any one of claims 1-21, wherein the one or more gates are patterned on the semiconductor surface.

23. A large-scale quantum processing architecture comprising:
a plurality of nodes, each node comprising a semiconductor substrate and a dielectric material forming an interface with the semiconductor substrate, each node further comprising a plurality of qubits embedded within the substrate, wherein each qubit includes two quantum dots, each quantum dot including a donor atom cluster and an electron shared between the two quantum dots, the node further comprising a plurality of gates for controlling the plurality of qubits; and
superconducting cavities arranged between neighboring nodes of the plurality of the nodes, each superconducting cavity coupling an edge qubit of a node with a corresponding edge qubit of a neighboring node.

24. The large-scale quantum processing system of claim 23, further comprising one or more interstitial nodes comprising classical control and readout electronics, and wherein the plurality of gates connects the corresponding plurality of qubits to the one or more interstitial nodes.

25. The large-scale quantum processing system of claim 24, wherein, in at least one of the nodes the qubits are formed such that one of the quantum dots of each qubit is formed on a first lithography plane and the other of the quantum dots of each qubit is formed on a second lithography plane.

26. The large-scale quantum processing system of claim 24, wherein, a quantum dot formed on the first lithography plane is tunnel coupled to a corresponding quantum dot formed on the second lithography plane.

27. The large-scale quantum processing system of claim 24, wherein the one or more gates are patterned as parallel control lines in a third lithography plane.

28. The large-scale quantum processing system of claim 23, wherein at least one node further comprising multiple metallic contacts positioned on the dielectric.

29. The large-scale quantum processing system of claim 23, wherein in at least one of the nodes, the quantum dots of the qubits are formed on a single lithography plane.

30. The large-scale quantum processing system of claim 23, wherein neighboring qubits on the node are coupled via floating gates.

31. The large-scale quantum processing system of claim 30, wherein the floating gates are located on the single lithography plane.

32. The large-scale quantum processing system of claim 23, wherein neighboring qubits on the node are coupled via direct dipole coupling.

33. The large-scale quantum processing system of claim 23, wherein in each qubit the donor atom cluster of one of the two quantum dots includes one donor atom and the donor atom cluster of the other of the two quantum dots includes two donor atoms.

34. The large-scale quantum processing system of claim 30, wherein the donor atom cluster that includes the two donor atoms is initialized with spins of the two donor atoms in opposite directions.

35. The large-scale quantum processing system of claim 30, wherein the donor atom cluster that includes the one donor atom is initialized with a spin up.
